(19) United States
(12) Patent Application Publication
(10) Pub. No.: US 2026/0040676 A1
(43) Pub. Date: Feb. 5, 2026

(54) MULTI-THRESHOLD VOLTAGE STACK OF A STACKED FIELD EFFECT TRANSISTOR

(71) Applicant: International Business Machines Corporation, Armonk, NY (US)

(72) Inventors: Ruqiang Bao, Niskayuna, NY (US); Chen Zhang, Santa Clara, CA (US); Junli Wang, Slingerlands, NY (US); Uzma Rana, Slingerlands, NY (US)

(21) Appl. No.: 18/793,464

(22) Filed: Aug. 2, 2024

(51) Int. Cl. H01L 27/092; H01L 21/28; H01L 21/822; H01L 21/8238; H01L 29/06; H01L 29/423; H01L 29/49; H01L 29/66; H01L 29/775; H01L 29/786

(52) U.S. Cl. CPC H10D 84/856; H01L 21/28088; H10D 30/014; H10D 30/43; H10D 30/6735; H10D 30/6739; H10D 30/6757; H10D 62/121; H10D 84/0177; H10D 84/038; H10D 88/01

(57) ABSTRACT

An exemplary semiconductor structure includes first, second and third field effect transistor (PET) stack on a substrate. Each of the first, second and third FET stacks includes a top and a bottom transistor. Each transistor has a channel region, a gate insulator and a gate work function layer. Each of the gate work function layers in the top transistors of the first, second and third FETs having a different composition.

BACKGROUND

The present invention relates generally to the electrical, electronic and computer arts and, more particularly, integrated circuit devices of different threshold voltages including stacked transistors.

An integrated circuit device including stacked transistors, such as field effect transistors (FETs), is desirable to reduce transistor area. However, it may be difficult to form multi-voltage transistors with a stack or from stack to stack which can be used across low power, mobile, and high-performance chips.

### BRIEF SUMMARY

Principles of the invention provide techniques for forming multi-threshold voltage transistors in one or more stacked FETs. In one aspect, an exemplary semiconductor structure includes first, second and third field effect transistor (FET) stack on a substrate. Each of the first, second and third FET stacks including a top and a bottom transistor. Each transistor having a channel region, a gate insulator and a gate work function layer. Each of the gate work function layers in the top transistors of the first, second and third FETs having a different composition.

In another aspect, another exemplary semiconductor structure includes first, second and third field effect transistor (FET) stack on a substrate. Each of the first, second and third FET stacks includes a top and a bottom transistor. Each transistor has a channel region, a gate insulator and a gate work function layer. Each of the gate work function layers in the top transistors of the first, second and third FETs having a different composition. The second top work function thickness is greater than each of the third top work function thickness and the first top work function thickness. A ratio of the third bottom work function thickness to a second bottom work function thickness is less than 1.2. And the first top width is less than the first bottom width.

In still a further aspect, an exemplary method of forming a semiconductor structure includes providing a first, a second and a third field effect transistor (FET) stacks, each FET stack having a planarization layer, a top channel region over a bottom channel region; a work function material around the top and bottom channel regions, and an insulator plug between the top channel region and the bottom channel region. Two of the FET stacks are blocked to leave an exposed FET stack. On the exposed FET stack, the planarization layer is recessed to allow removal of the work function material from the top channel regions of the exposed FET stack. Next, the planarization layer is removed from the exposed FET stack and a second work function material is formed around the top channel regions of the exposed FET stack. Then the blocked FET stacks are unblocked and the process is repeated for another FET stack. Each time a different work function material composition formed around the top channel region of the exposed FET stack. For example, unblocking the second and third FET stacks, blocking the first and third FET stacks to leave the second FET stack exposed, recessing the planarization layer of the second FET, removing the work function material from the top channel regions of the second FET, removing the planarization layer of the second FET, forming a third work function material around the top channel regions of the second FET, unblocking the second and third FET stacks, blocking the first and second FET stacks to leave the third FET stack exposed, recessing the planarization layer of the third FET, removing the work function material from the top channel regions of the third FET, removing the planarization layer of the third FET, and forming a fourth work function material around the top channel regions of the third FET in which the composition of the second, third and fourth work function materials are different from each other.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Allows further scaling of semiconductor structures using stacked transistors.
Allows a multi-threshold opposite polarity stacked transistor (NFET over PFET or vice versa) which provides greater design flexibility from low power to high performance applications and points in between.
Allows a “fix” to reliability and leakage issues of integrated circuit manufacturing flow designed for low power or mobile technology making the process flow suitable for high-performance computing.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a top view of an exemplary semiconductor structure in accordance with aspects of the invention;

FIG. 2 is a cross-section along a gate region of a stacked FET taken along the line C-C′ of FIG. 1 in accordance with aspects of the invention;

FIG. 3 lists is exemplary steps of a method for creating the structures of FIGS. 1, 2 and 9 in accordance with aspects of the invention; and

FIGS. 4A-9 are exemplary views of aspects of various steps of FIG. 3 in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

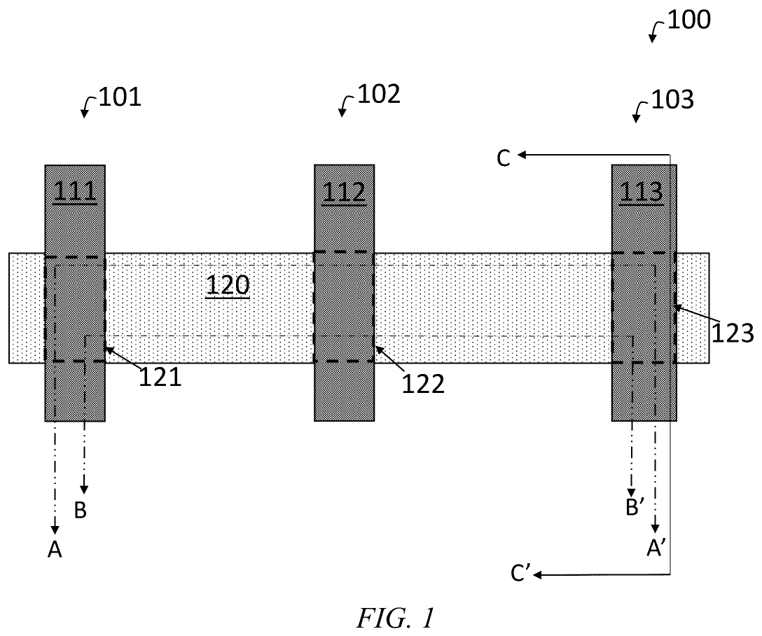

Aspects of invention provide for multi-threshold voltage stacked transistors and methods of making the same. FIG. 1 is a top view of an exemplary semiconductor structure 100 in accordance with aspects of the invention. The semiconductor structure 100 includes multiple FET stacks, for example, first FET stack 101, second FET stack 102 and third FET stack 103, on the same substrate and each having a different threshold voltage. For example, each FET stack 10X (using “X” to generically refer to any or all of the first, second or third FET stacks) may have a different operating voltage regime (e.g. low voltage (LVT), standard or regular voltage (RVT), or high threshold voltage (HVT)). HVT has the advantage of less leakage current and therefore use less power, but on other hand HVT FETs are slower to switch, the opposite is true with LVT FETs. RVT FETs have performance between that of LVT and RVT FETs. As a result, because HVT FET stacks have less power consumption, but its switch timing is not optimal, they are used in power critical functions. Meanwhile, because LVT stacked FETs have more power consumption but excellent switching speed, they are used in time critical functions such as high frequency applications. By using a variety of threshold voltages on the same chip, a lower power integrated circuit can be achieved. The FET stack 10X may also be a logic transistor or an input/out transistor.

Still referring to the FIG. 1 embodiment of the semiconductor structure 100, each FET stack 10X has a gate region 11X (first gate region 111, second gate region 112, and third gate region 113) overlying an active area 120. The active area 120 is composed of semiconductor material. Where the active area 120 and gate region 11X intersect there is a channel region 12X (see dotted rectangles of first channel region 121, second channel region 122 and third channel region 123) of semiconductor material. While the embodiment of FIG. 1 shows each gate region 11X over the same active area 120, each gate region 11X could be over the three different active areas on the same substrate. Likewise, in other embodiments, one gate region line (albeit with three regions of different gate insulator and/or gate work function layers) could be over three different active areas.

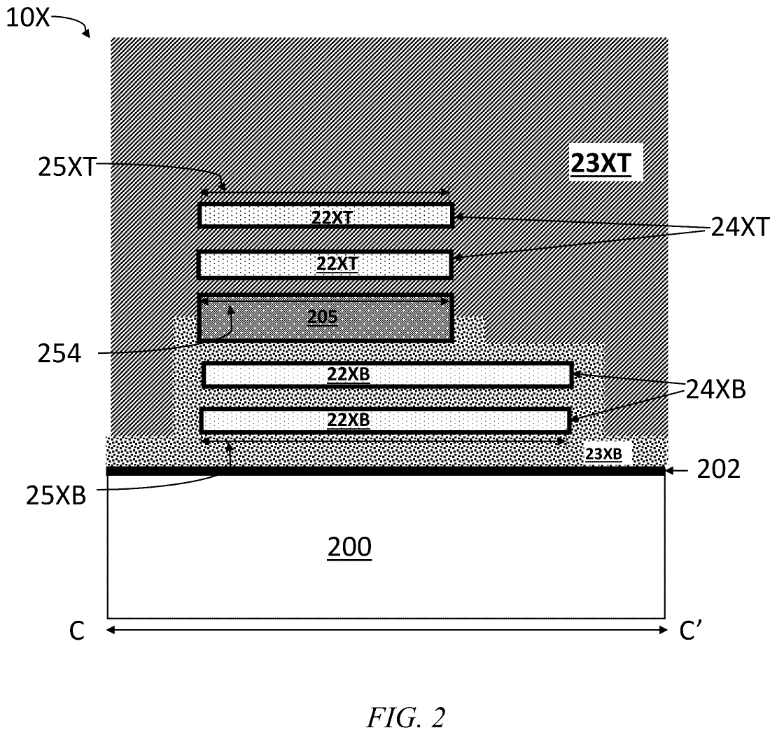

FIG. 2 is a cross-section along a gate region 11X of a FET stack 10X taken along the line C-C′ of FIG. 1. The FET stack 10X is built on a substrate 200 comprising a semiconductor. The FET stack 10X has a top portion with top channel regions 22XT and a bottom portion with bottom channel regions 22XB. The top and bottom portions are separated by an insulator plug 205. Within a given FET Stack 10X, the top portion and bottom portions are transistors having opposite polarity. For example, the top portion can be PFET while the bottom portion is an NFET, or vice versa. A dielectric 202 is optionally between the substrate 200 a bottom gate work function layer 23XB (any of first bottom gate work function layer 231B, second bottom gate work function layer 232B, and third bottom gate work function layer 233B of the first, second or third FET stacks, respectively). The bottom gate work function layer 23XB wraps around the bottom channel regions 22XB (any of first bottom channel region 221B, second bottom channel region 222B, and third bottom channel region 223B of the first, second or third FET stacks, respectively) and a portion of insulator plug 205. Above the insulator plug 205, and separated by the top gate work function layer 23XT (any of first top gate work function layer 231T, second top gate work function layer 232T, and third gate top work function layer 233T of the first, second or third FET stacks, respectively) are the top channel regions 22XT (any of first top channel region 221T, second top channel region 222T, and third top channel region 223T of the first, second or third FET stacks, respectively). Between the top channel regions 22XT and the top gate work function layers 23XT are top gate insulators 24XT (any of first top gate insulators 241T, second top gate insulators 242T, and third top gate insulators 243T of the first, second or third FET stacks, respectively). Likewise, Between the bottom channel regions 22XB and the bottom gate work function layers 23XB are bottom gate insulators 24XB (any of first bottom gate insulators 241B, second bottom gate insulators 242B, and third bottom gate insulators 243B of the first, second or third FET stacks, respectively). The top channel regions 22XT have a top width 25XT (any of first top width 251T, second top width 252T, and third gate top width 253T of the first, second or third FET stacks, respectively). The bottom channel regions 22XB have a bottom width 25XB (any of first bottom width 251B, second bottom width 252B, and third gate bottom width 253B of the first, second or third FET stacks, respectively). The top width is narrower than the bottom width. The insulator plug 205 separating the bottom and top channel regions has an insulator plug width 254 which can be the equal to or less than the top width 25XT of the top channel region 12XT. The top channel region 12XT can have one side vertically aligned with the bottom channel region 12XB and the insulator plug 205 (as in FIG. 2) or can be centered over the insulator plug 205.

The gate insulators can include an interfacial layer, typically, but not limited to a silicon oxide, and a high dielectric constant material, typically, but not limited to hafnium oxide. High dielectric constant materials can be those with dielectric constant greater than 7. Variations of gate insulator thickness, gate work function layer thickness and/or gate work function layer composition are used to modulate threshold voltage. The gate insulators of the invention may include dipole elements to tune and center the threshold voltage. By way of example and not limitation, a dipole element can include lanthanum (La), yttrium (Y), strontium (Sr), lutetium (Lu), barium (Ba) or magnesium (Mg), aluminum (Al), titanium (Ti), tantalum (Ta) or scandium (Sc). The gate insulators can have the same or different thicknesses across the various FET stacks 10X. In cases in which the gate insulators have different thicknesses, the higher threshold voltage transistor can have thicker gate insulator total thickness. To achieve the thickness difference at least one of the interfacial layer and the high-k layer has a different thickness.

Turning to the top gate work function layers 23XT and bottom gate work function layers 23XB within a given FET stack 10X, the top and bottom layers are directly connected to each other. The top gate work function layers 23XT, that is the first top gate work function layers 231T, the second top gate work function layers 232T and the third top gate work function layers 233T, are different from each other in either thickness, composition or both. Composition can include different materials or a material having a different concentration(s) of the same element(s). Similarly, the same can be true for the bottom gate work function layers 24XB. Here, each of the first bottom gate work function layers 231B, the second bottom gate work function layers 232B and the third bottom gate work function layers 233B, are different from each other in either thickness, composition or both. PFET gate work function layers can include one or more of the following materials: TiN, WN, TiAlC within the FET stack 10X. An example of NFET gate work function layers can include one or more of the following materials: TIC, TiN, TiAl, and TiAlC, and Ti or Al containing alloy(s). In either the NFET or PFET case, the Al percentage can vary from one FET stack 10X to another. Also, the thicknesses of one or more of the materials making up the gate work function layer can vary from one FET stack 10X to another. Table 1 below gives an exemplary top gate work function layers 24XT and bottom gate work function layers 24XB in a case where the top transistor is a PFET and the bottom transistor is an NFET in three FET stacks 10X having different threshold voltages.

TABLE 1

| | 1^{st} FET Stack | 2nd FET Stack | 3rd FET Stack |
|---|---|---|---|
| | 101 | 102 | 103 |
| Threshold | Lowest | Intermediate | Highest |
| Voltage | | | |
| Top gate | (1) metal nitride | (1) metal nitride | (1) metal nitride, |
| work | layer (20-50A). | (15-40A), and | and |
| function | Exemplary metal | (2) a Ti or Al | (2) a Ti or Al |
| layers | nitride layers | containing alloy | containing alloy |
| 23XT | include TiN, | layer. | layer. |
| | WN, MoN, and | | The metal nitride |
| | TaN | | is thinner than (2nd |
| | | | FET Stack 102), |
| | | | such as 10-30A, or |
| | | | the alloy layer is |
| | | | thicker than (2nd |
| | | | FET Stack 102) |
| Bottom | (1) metal nitride | Similar stack as | Similar stack as |
| gate work | (5-10A), and | 1^{st} FET Stack | 2nd FET Stack 102 |
| function | (2) a Ti or Al | 101 but with one | but with one of |
| layers 23XB | containing alloy | of | (a) thinner Ti or Al |
| | layer, and | (a) thinner Ti or | contained alloy |
| | (3) another metal | Al containing | layer, or |
| | nitride layer | alloy layer, or | (b) a different Ti or |
| | (10-15 Å) | (b) lower Al or | Al contained alloy |
| | | Ti concentration, | layer, either by |
| | | or | concentration or |
| | | (c) different Ti | different elements |
| | | or Al containing | |
| | | alloy layer, | |
| | | either by | |
| | | concentration or | |
| | | different | |
| | | elements | |

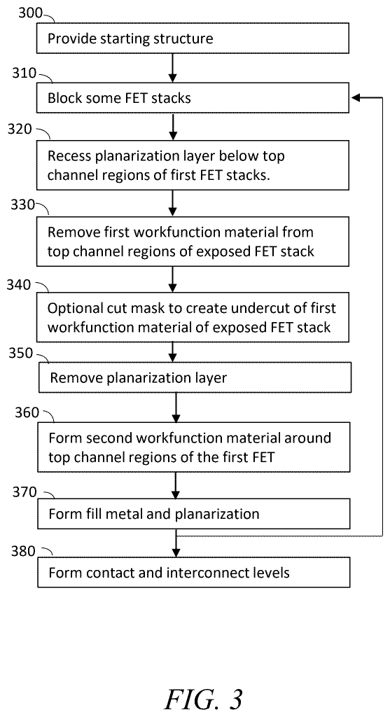

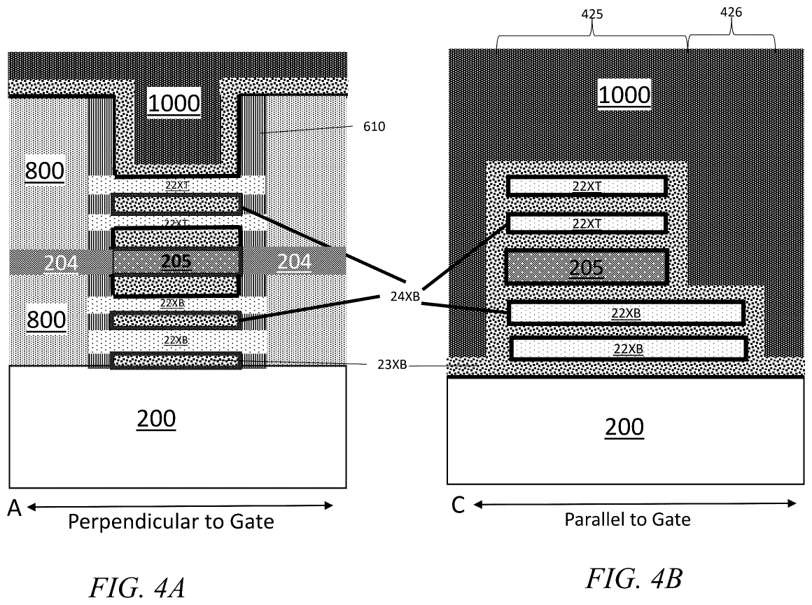

An exemplary method of making the semiconductor structure according to aspects of the invention are listed in FIG. 3. In step 300, a starting structure known in the art is provided. The structure includes substrate 200 having three partially built stacked FETs on a substrate 200 in a top-down configuration as described in conjunction with FIG. 1. Referring to FIG. 4A and 4B, one of the stacked FETs is shown in cross-section along the A-A′ line of FIG. 1 (i.e. FIG. 4A) while the same stacked FETs is shown in cross-section along the C-C′ line of FIG. 1 (i.e. FIG. 4B). The structures are stacked FETS having the same work function materials and gate insulators in the bottom and top channel regions A planarization layer 1000 covers the structures. The planarization layer can be an optical planarization layer. Referring to FIG. 4A, the structure already has source/drain 800 material and inner spacers 610 formed. Referring to FIG. 4B (and FIG. 2), because the channel regions top width 25XT is less than the bottom width 25XB, there is a full heigh portion 425 and a half height portion 426 of the FET stack.

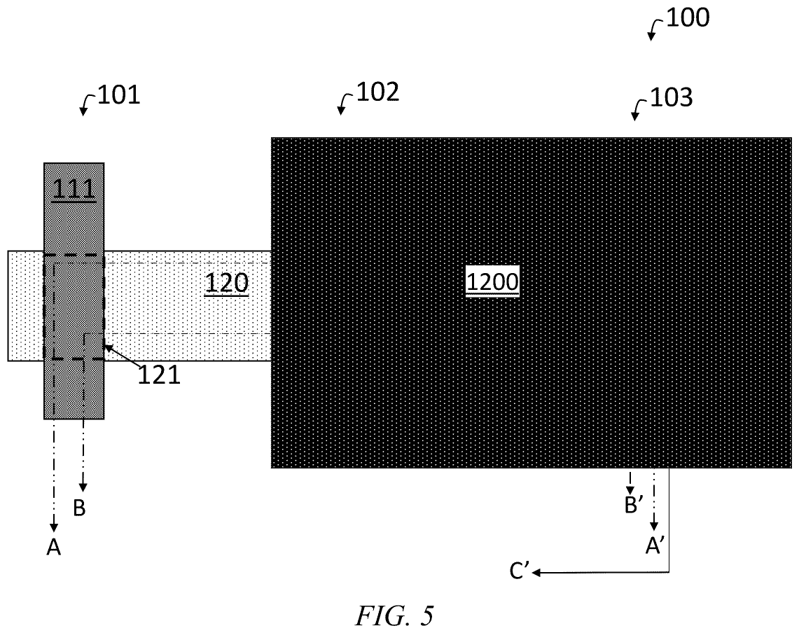

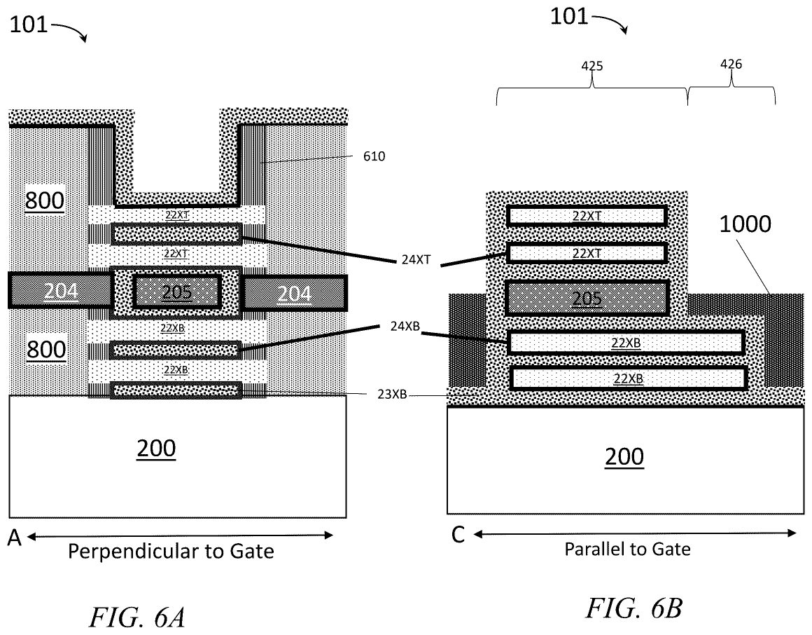

In step 310 and referring to FIG. 5 showing a top-down view, a blocking mask 1200 is formed over the second FET stack 102 and the third FET stack 103 while the first FET stack 101 remains exposed. Next, while the other FETS stacks are blocked, in steps 320 and 330 the planarization layer 1000 and the bottom gate work function layer 23XB in the first FET stack 101 are recessed below the top channel regions 22XT (See FIGS. 6A and 6B depict cross-sections perpendicular and parallel to the gate respectively).

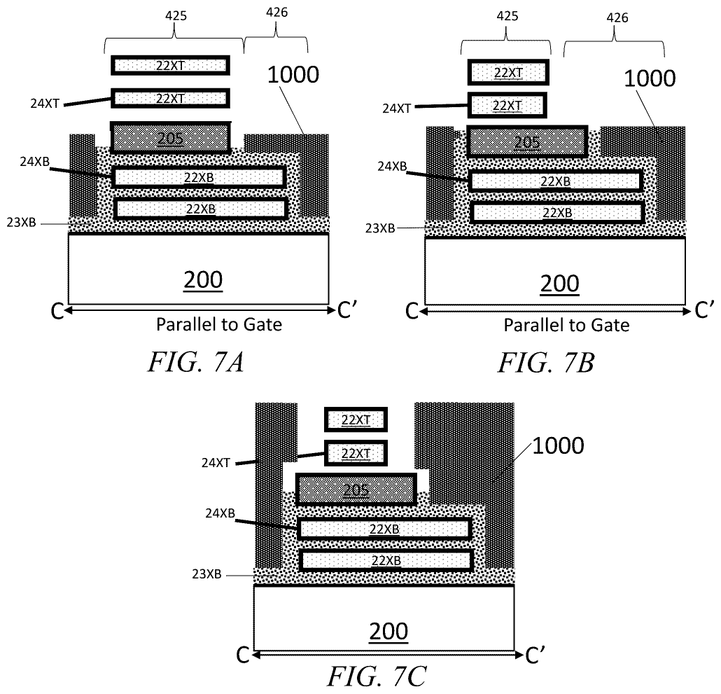

Turning to FIGS. 7A-C, variations in the recessing of planarization layer 1000 and channel regions contemplated in the invention are depicted. FIG. 7A shows a version in which the top channel regions 22XT align on one side with the bottom channel regions 22XB and the insulator plug 205. On the other side, top channel regions 22XT align with the insulator plug 205 such that the top channel regions 22XT and insulator plug 205 have the same width which is less than the width of the bottom channel regions 22XB. With respect to planarization recessing, FIG. 7A depicts a variation in which the planarization layer 1000 is recessed to be even with bottom gate work function layer 23XB and within the height of the insulator plug 205.

The FIG. 7B variation depicts top channel regions 22XT aligning with the insulator plug 205, however the width of the top channel regions 22XT is less than the width of insulator plug 205 and is less than the width of the bottom channel regions 22XB. For example, the top channel region 22XT can be up to half of the width of the insulator plug 205 have the same width which is less than the width of the bottom channel regions 22XB. With the relatively narrow top channel regions 22XT, less time is needed to clean material between adjacent top channel regions 22XT which can lead to less vertical recessing of bottom gate work function layer 23XB.

The FIG. 7C variation depicts top channel regions 22XT do not align with the sides of insulator plug 205 or bottom channel regions 22XB, but instead are somewhat centered over the insulator plug 205. In this variation the width of the top channel regions 22XT is less than the width of insulator plug 205 and is less than the width of the bottom channel regions 22XB. With respect to planarization recessing, in FIG. 7C the planarization layer is not recessed below the top channel region 22XT, instead a cut mask is used (optional step 340 of FIG. 3) to recess bottom gate work function layer 23XB to a point within the height of the insulator plug 205. By putting the top channel regions 22XT in the center and adding a cut mask to increase path of undercut, wider nanosheet can be used for top channel regions 22XT, which can help improve device performance.

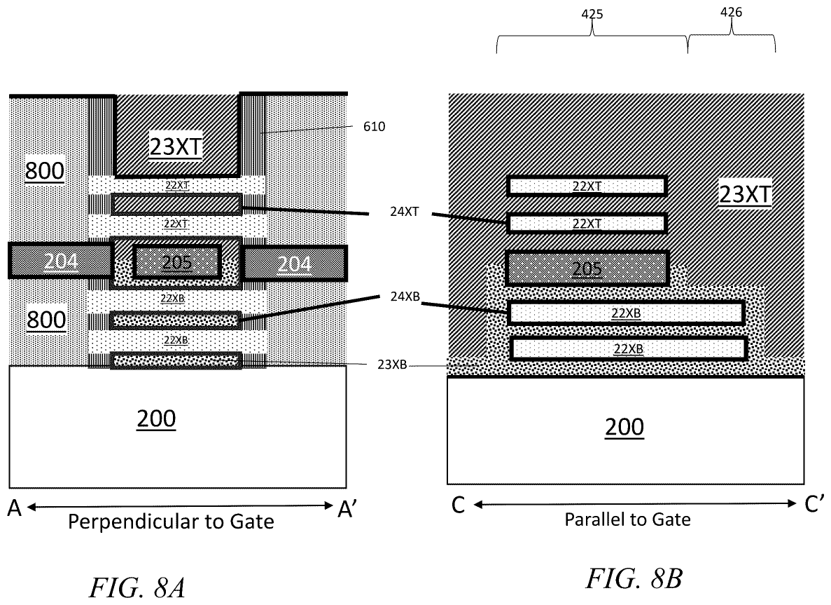

In step 350, the planarization layer 1000 is removed from the first FET stack 101. And in step 360 a top work function layer 230T is formed around the top channel region 22XT (See FIGS. 8A-8B). Gate electrode formation such as W deposition is followed after top work function layer 230T is formed. And then a new planarization is formed to open other Vt pairs of devices if not completing all Vt devices yet.

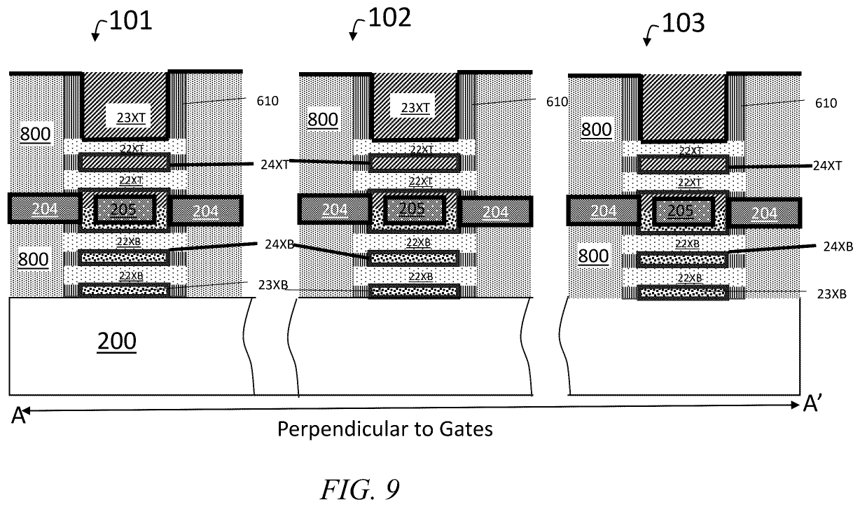

Steps 310 through 370 are repeated so that each stacked FET of a certain threshold voltage is exposed while the stacked FETs of the other threshold voltages are blocked. Once all stacked transistors are made, the method continues to step 370 in which any gate fill metal is formed (typically tungsten) and the contact and interconnect levels can be formed in step 380. The result will be stacked n and p transistors on the same substrate having different threshold voltages as depicted in FIG. 9 where the first FET stack 101 can be a low voltage transistor of n (or p) doping on the top channel region 221T and p (or n) doping on the bottom channel region 221B, where the second FET stack 102 can be a regular voltage transistor of n (or p) doping on the top channel region 222T and p (or n) doping on the bottom channel region 222B, and where the third FET stack 103 can be a high voltage transistor of n (or p) doping on the top channel region 223T and p (or n) doping on the bottom channel region 223B. In each case, the top work function layer 23XT is directly connected to the bottom work function layer 23XB.

In summary, semiconductor structure 100 includes a first field effect transistor (FET) stack 101, a second field effect transistor (FET) stack 102, and a third field effect transistor (FET) stack 103 on a substrate 200. Each of the FET stacks including a top transistor having a top channel region 22XT having a top width 25XT, a top gate insulator 24XT having a top insulator thickness, and a top gate work function layer 23XT having a top composition and a top work function thickness on the top channel region 22XT. Each FET stack also including a top transistor a bottom transistor having a bottom channel region 22XB having a bottom width 25XB, a bottom gate insulator 24XB having a bottom insulator thickness, and a bottom gate work function layer 23XB having a bottom work function thickness on the bottom gate insulator 24XB. The compositions of the top gate work function layers 23XT are different in each of the first field effect transistor (FET) stack 101, the second field effect transistor (FET) stack 102, and the third field effect transistor (FET) stack 103.

In some embodiments the composition of the first top gate work function layer 231T lacks aluminum, while the second top gate work function layer 232T has a second percentage of aluminum and the third top gate work function layer 233T has a third percentage of aluminum in which the second percentage is greater than the third percentage.

In some embodiments a composition of the third bottom gate work function layer 233B is different from each of the compositions of the second bottom gate work function layer 232B and the first bottom gate work function layer 231B.

In some embodiments the thickness of the second top gate work function layer 232T is greater than the thicknesses of each of the third top gate work function layer 233T and the first top gate work function layer 231T.

In some embodiments the thickness of the second bottom gate work function layer 232B is less than each of the third bottom gate work function layer 233B and the first bottom gate work function layer 231B.

In some embodiments a ratio of the thicknesses of the first bottom gate work function layer 231B to a second bottom gate work function layer 232B is less than 1.2.

In some embodiments a ratio of the thicknesses of the third bottom gate work function layer 233B to a second bottom gate work function layer 232B is less than 1.2.

In some embodiments, a dipole element is in at least one of the first top gate insulator 241T, the second top gate insulator 242T, the third top gate insulator 243T, first bottom gate insulator 241B, the second bottom gate insulator 3242B, the third bottom gate insulator 243B in which the dipole element comprises at least one of lanthanum (La), yttrium (Y), strontium (Sr), lutetium (Lu), barium (Ba), magnesium (Mg), aluminum (Al), titanium (Ti), tantalum (Ta) and scandium (Sc).

In some embodiments, the first top gate work function layer 231T and the first bottom gate work function layer 231B are directly connected to each other, the second top gate work function layer 232T and the second bottom gate work function layer 232B are directly connected to each other, and the third top gate work function layer 233T and the third bottom gate work function layer 233B are directly connected to each other.

In some embodiments, the width of the first top channel region 221T is less than the width of the first bottom channel region 221B.

In some embodiments, the thickness of the third top insulator 243T is greater than each of the second top insulator 242T and first top insulator 241T.

In some embodiments, the third FET stack 103 is an input/output FET stack.

In some embodiments, the third FET stack 103 is a regular voltage FET stack.

In some embodiments, the thickness of the third top insulator 243T comprises a silicon oxide interfacial of about 2 nm and a hafnium oxide dielectric layer.

In some embodiments the thickness of the third bottom insulator 243B is greater than each of the second bottom insulator 242B thickness and first bottom insulator 241B thickness.

In further summary, semiconductor structure 100 includes a first field effect transistor (FET) stack 101, a second field effect transistor (FET) stack 102, and a third field effect transistor (FET) stack 103 on a substrate 200. Each of the FET stacks including a top transistor having a top channel region 22XT having a top width 25XT, a top gate insulator 24XT having a top insulator thickness, and a top gate work function layer 23XT having a top composition and a top work function thickness on the top channel region 22XT. Each FET stack also including a top transistor a bottom transistor having a bottom channel region 22XB having a bottom width 25XB, a bottom gate insulator 24XB having a bottom insulator thickness, and a bottom gate work function layer 23XB having a bottom work function thickness on the bottom gate insulator 24XB. The compositions of the top gate work function layers 23XT are different in each of the first field effect transistor (FET) stack 101, the second field effect transistor (FET) stack 102, and the third field effect transistor (FET) stack 103. The compositions of the bottom gate work function layers 23XB are different in each of the first field effect transistor (FET) stack 101, the second field effect transistor (FET) stack 102, and the third field effect transistor (FET) stack 103. The thickness of the second top gate work function layer 232T is greater than each of the third top gate work function layer 233T and the first top gate work function layer 232T in which a ratio of the thickness of the third bottom gate work function layer 233T to a second bottom gate work function layer 232T is less than 1.2. A width of the first top channel region 22XT is less than the bottom channel region 22XB width.

In summary, an exemplary method of forming semiconductor structure 100 includes providing a first, a second and a third field effect transistor (FET) stacks, each FET stack having a planarization layer 1000, a top channel region 22XT over a bottom channel region 22XB; a work function layer around the top and bottom channel regions, and an insulator plug 205 between the top channel region 22XT and the bottom channel region 22XB, blocking the second FET stack 102 and third FET stack 103 to leave the first FET stack 101 exposed; recessing the planarization layer 1000 of the first FET stack 101, removing the work function layer from the top channel regions 22XT of the first FET stack 101, removing the planarization layer 1000 of the first FET stack 101, forming a second work function layer 23XT around the top channel regions 22XT of the first FET stack 101, unblocking the second FET stack 102 and the third FET stack 103, blocking the first FET stack 101 and third FET stack 104 to leave the second FET stack 103 exposed, recessing the planarization layer 1000 of the second FET stack 102, removing the work function layer 23XT from the top channel regions 22XT of the second FET stack 102, removing the planarization layer 1000 of the second FET stack 102, forming a third work function layer 23XT around the top channel region 22XT of the second FET, unblocking the second FET Stack 102 and third FET stack 103, blocking the first FET stack 101 and the second FET stack 102 to leave the third FET stack 103 exposed, recessing the planarization layer 1000 of the third FET stack 103, removing the work function layer 23XT from the top channel region 22XT of the third FET stack 103, removing the planarization layer 1000 of the third FET stack 103, and forming a fourth work function layer 23XT around the top channel region 22XT of the third FET stack 103, in which a composition of the second, third and fourth work function layers are different from each other.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for case of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a first field effect transistor (FET) stack on a substrate, the first FET stack comprising:
a first top transistor comprising:
a first top channel region having a first top width;
a first top gate insulator having a first top insulator thickness; and
a first top gate work function layer having a first top composition and a first top work function thickness on the first top channel region; and
a first bottom transistor comprising:
a first bottom channel region having a first bottom width;
a first bottom gate insulator having a first bottom insulator thickness; and
a first bottom gate work function layer having a first bottom work function thickness on the first bottom gate insulator;
a second FET stack on the substrate, the second FET stack comprising:
a second top transistor comprising:
a second top channel region having a second top width;
a second top gate insulator having a second top insulator thickness; and
a second top gate work function layer having a second top composition and second top work function thickness on the second top channel region; and
a second bottom transistor comprising:
a second bottom channel region a second bottom width;
a second bottom gate insulator having a second bottom insulator thickness; and
a second bottom gate work function layer having a second bottom work
function thickness on the second bottom gate insulator; and
a third FET stack on the substrate, the third FET stack comprising:
a third top transistor comprising:
a third top channel region having a third top width;
a third top gate insulator having a third top insulator thickness; and
a third top gate work function layer having a third top composition and a third top work function thickness on the third top channel region; and
a third bottom transistor comprising:
a third bottom channel region having third bottom width;
a third bottom gate insulator having a third bottom insulator thickness; and
a third bottom gate work function layer having a third bottom work function thickness on the third bottom gate insulator; and
wherein the first top composition, the second top composition and the third top composition are different.

2. The semiconductor structure of claim 1, the first top composition lacks aluminum, the second top composition has a second percentage of aluminum and the third top composition a third percentage of aluminum; and
wherein the second percentage is greater than the third percentage.

3. The semiconductor structure of claim 2, wherein a composition of the third bottom gate work function layer is different from each of a composition of the second bottom gate work function layer and a composition of the first bottom gate work function layer.

4. The semiconductor structure of claim 2, the second top work function thickness is greater than each of the third top work function thickness and the first top work function thickness.

5. The semiconductor structure of claim 2, the wherein the second bottom work function thickness is less than each of the third bottom work function thickness and the first bottom work function thickness.

6. The semiconductor structure of claim 2, the wherein a ratio of the first bottom work function thickness to the second bottom work function thickness is less than 1.2.

7. The semiconductor structure of claim 6, the wherein a ratio of the third bottom work function thickness to a second bottom work function thickness is less than 1.2.

8. The semiconductor structure of claim 2, the further comprising a dipole element in at least one of the first top gate insulator, the second top gate insulator, the third top gate insulator, the first bottom gate insulator, the second bottom gate insulator, the third bottom gate insulator wherein the dipole element comprises at least one of lanthanum (La), yttrium (Y), strontium (Sr), lutetium (Lu), barium (Ba), magnesium (Mg), aluminum (Al), titanium (Ti), tantalum (Ta) and scandium (Sc).

9. The semiconductor structure of claim 2, wherein the first top gate work function layer and the first bottom gate work function layer are directly connected to each other;
wherein the second top gate work function layer and the second bottom gate work function layer are directly connected to each other; and
wherein the third top gate work function layer and the third bottom gate work function layer are directly connected to each other.

10. The semiconductor structure of claim 1, wherein the first top width is less than the first bottom width.

11. The semiconductor structure of claim 10, wherein the third top insulator thickness is greater than each of the second top insulator thickness and the first top insulator thickness.

12. The semiconductor structure of claim 11, wherein the third FET stack is an input/output FET stack.

13. The semiconductor structure of claim 11, wherein the third FET stack is a regular voltage FET stack.

14. The semiconductor structure of claim 11, wherein the third top insulator thickness comprises a silicon oxide interfacial of about 2 nm and a hafnium oxide dielectric layer.

15. The semiconductor structure of claim 10, wherein the third bottom insulator thickness is greater than each of the second bottom insulator thickness and the first bottom insulator thickness.

16. The semiconductor structure of claim 15, wherein the third FET stack is an input/output FET stack.

17. The semiconductor structure of claim 15, wherein the third FET stack is an regular voltage FET stack.

18. The semiconductor structure of claim 15, wherein the third top insulator thickness comprises a silicon oxide interfacial of about 2 nm and a hafnium oxide dielectric layer.

19. A semiconductor structure comprising:
a first field effect transistor (FET) stack on a substrate, the first FET stack comprising:
a first top transistor comprising:
a first top channel region having a first top width;
a first top gate insulator having a first top insulator thickness; and
a first top gate work function layer having a first top composition and a first top work function thickness on the first top channel region; and
a first bottom transistor comprising:
a first bottom channel region having a first bottom width;
a first bottom gate insulator having a first bottom insulator thickness; and
a first bottom gate work function layer having a first bottom work function thickness on the first bottom gate insulator;
a second FET stack on the substrate, the second FET stack comprising:
a second top transistor comprising:
a second top channel region having a second top width;
a second top gate insulator having a second top insulator thickness; and
a second top gate work function layer having a second top composition and second top work function thickness on the second top channel region; and
a second bottom transistor comprising:
a second bottom channel region a second bottom width;
a second bottom gate insulator having a second bottom insulator thickness; and
a second bottom gate work function layer having a second bottom work function thickness on the second bottom gate insulator; and
a third FET stack on the substrate, the third FET stack comprising:
a third top transistor comprising:
a third top channel region having a third top width;
a third top gate insulator having a third top insulator thickness; and
a third top gate work function layer having a third top composition and a third top work function thickness on the third top channel region; and
a third bottom transistor comprising:
a third bottom channel region having third bottom width;
a third bottom gate insulator having a third bottom insulator thickness; and
a third bottom gate work function layer having a third bottom work function thickness on the third bottom gate insulator; and
wherein the first top composition, the second top composition and the third top composition are different;
wherein a composition of the third bottom gate work function layer is different from each of a composition of the second bottom gate work function layer and a composition of the first bottom gate work function layer
wherein the second top work function thickness is greater than each of the third top work function thickness and the first top work function thickness;
wherein a ratio of the third bottom work function thickness to the second bottom work function thickness is less than 1.2; and
wherein the first top width is less than the first bottom width.

20. A method of forming semiconductor structure comprising:
providing a first, a second and a third field effect transistor (FET) stacks, each FET stack having a planarization layer, a top channel region over a bottom channel region; a work function layer around the top and bottom channel regions, and an insulator plug between the top channel region and the bottom channel region;
blocking the second and third FET stacks to leave the first FET stack exposed;
recessing the planarization layer of the first FET stack;
removing the work function layer from the top channel regions of the first FET stack;
removing the planarization layer of the first FET stack;
forming a second work function layer around the top channel regions of the first FET stack;
unblocking the second and third FET stacks;
blocking the first and third FET stacks to leave the second FET stack exposed;
recessing the planarization layer of the second FET stack;
removing the work function layer from the top channel regions of the second FET stack;
removing the planarization layer of the second FET stack;
forming a third work function layer around the top channel regions of the second FET stack;
unblocking the second and third FET stacks;
blocking the first and second FET stacks to leave the third FET stack exposed;
recessing the planarization layer of the third FET stack;
removing the work function layer from the top channel regions of the third FET;
removing the planarization layer of the third FET stack; and
forming a fourth work function layer around the top channel regions of the third FET stack;
wherein a composition of the second, third and fourth work function layers are different from each other.
